(19) United States
(12) Patent Application Publication
(10) Pub. No.: US 2026/0076034 A1
(43) Pub. Date: Mar. 12, 2026

(54) DISPLAY DEVICE AND ELECTRONIC DEVICE

(71) Applicant: Samsung Display Co., Ltd., Yongin-si (KR)

(72) Inventors: SUNKWUN SON, Yongin-si (KR); CHEOL-GON LEE, Yongin-si (KR)

(73) Assignee: Samsung Display Co., Ltd., Yongin-si (KR)

(21) Appl. No.: 19/314,121

(22) Filed: Aug. 29, 2025

(30) Foreign Application Priority Data
Sep. 12, 2024 (KR) 10-2024-0124787

(51) Int. Cl. H10K 59/121; H10K 59/131; H10K 59/35

(52) U.S. Cl. CPC H10K 59/1213; H10K 59/131; H10K 59/353

(57) ABSTRACT

Provided is a display device including a substrate, a first transistor disposed on the substrate and including a first semiconductor layer and a first gate electrode, a second transistor disposed on the first transistor and including a second semiconductor layer and a second gate electrode, and a light-emitting element disposed on the second transistor and electrically connected to the first transistor, wherein the first gate electrode of the first transistor and the second semiconductor layer of the second transistor are electrically connected through a contact hole.

### CROSS-REFERENCE TO RELATED APPLICATIONS

This application claims priority to and benefits of Korean Patent Application No. 10-2024-0124787 under 35 U.S.C. § 119, filed on September 12, 2024, in the Korean Intellectual Property Office, the entire contents of which are incorporated herein by reference.

### BACKGROUND

### 1. Technical Field

One or more embodiments relate to a display device and an electronic device.

### 2. Description of the Related Art

Nowadays, various flat panel display devices are developed for overcoming many drawbacks of cathode ray tubes such as heavy weight and bulk volume. Flat panel display devices may include liquid crystal displays (LCDs), field emission displays (FEDs), plasma display panels (PDPs), organic light-emitting diode (OLED) displays, etc.

Among those flat panel display devices, organic light-emitting diode (OLED) displays output images using organic light-emitting diodes, which emit light through the recombination of electrons and holes. These OLED displays are receiving attention as next-generation displays by virtue of fast response speed and operation with low power consumption.

### SUMMARY

One or more embodiments provide a display device with improved integration density and an electronic device including the display device.

However, exemplary embodiments of the disclosure are not restricted to the one set forth herein. The other exemplary embodiments of the disclosure will become more apparent to one of ordinary skill in the art to which the disclosure pertains by referencing the detailed description of the disclosure given below.

Additional aspects will be set forth in part in the description which follows and, in part, will be apparent from the description, or may be learned by practice of the presented embodiments of the disclosure.

According to one or more embodiments, a display device includes a substrate, a first transistor disposed on the substrate and including a first semiconductor layer and a first gate electrode, a second transistor disposed on the first transistor and including a second semiconductor layer and a second gate electrode, and a light-emitting element disposed on the second transistor and electrically connected to the first transistor, wherein the first gate electrode of the first transistor and the second semiconductor layer of the second transistor are electrically connected to each other through a contact hole.

In an embodiment, the display device may further include a conductive layer disposed on an insulating layer which covers the second semiconductor layer, and electrically connected to the first gate electrode and the second semiconductor layer through the contact hole, and at least a portion of the conductive layer may vertically overlap the first gate electrode and the second semiconductor layer.

In an embodiment, the contact hole may expose a side surface of a source region of the second transistor.

In an embodiment, the display device may further include a third transistor, wherein the third transistor and the second transistor may be disposed on a same layer, and the third transistor may include the second semiconductor layer and a third gate electrode.

In an embodiment, the display device may further include a first scan line and a second scan line disposed on a same layer between the first transistor and the second transistor, the first scan line may form a dual gate of the second transistor together with the second gate electrode, and the second scan line may form a dual gate of the third transistor together with the third gate electrode.

In an embodiment, the first scan line and the second scan line may be arranged parallel to each other.

In an embodiment, the display device may further include a first voltage line and an initialization voltage line disposed on a same layer between the second gate electrode and the light-emitting element.

In an embodiment, the first voltage line and the initialization voltage line may be arranged parallel to the first scan line.

In an embodiment, two sub-pixels may share a first voltage, and the two sub-pixels may be arranged adjacent to each other in a direction perpendicular to a longitudinal direction of the first voltage line with respect to the first voltage line.

In an embodiment, the first semiconductor layer may include polycrystalline silicon and the second semiconductor layer may include an oxide semiconductor.

According to one or more embodiments, a display device includes a substrate including a display area and a peripheral area disposed outside the display area, a plurality of sub-pixels disposed in the display area, and a plurality of first voltage lines extending in a first direction and that apply a first voltage to the plurality of sub-pixels, wherein two sub-pixels share a first voltage line of the plurality of first voltage lines, and the two sub-pixels may be arranged adjacent to each other in a second direction perpendicular to the first direction with respect to the first voltage line.

In an embodiment, the two sub-pixels may be symmetrical with respect to the first voltage line.

In an embodiment, each of the plurality of sub-pixels may include a first transistor disposed on the substrate and including a first semiconductor layer and a first gate electrode, a second transistor disposed on the first transistor and including a second semiconductor layer and a second gate electrode, and a light-emitting element disposed on the second transistor and electrically connected to the first transistor, and the first gate electrode of the first transistor and the second semiconductor layer of the second transistor may be electrically connected through a contact hole.

In an embodiment, the display device may further include a conductive layer disposed on an insulating layer which covers the second semiconductor layer, and electrically connected to the first gate electrode and the second semiconductor layer through the contact hole, and at least a portion of the conductive layer may vertically overlap the first gate electrode and the second semiconductor layer.

In an embodiment, the contact hole may expose a side surface of a source region of the second transistor.

In an embodiment, the display device may further include a third transistor, wherein the third transistor and the second transistor may be disposed on a same layer, and the third transistor may include the second semiconductor layer and a third gate electrode.

In an embodiment, the display device may further include a first scan line and a second scan line disposed on a same layer between the first transistor and the second transistor, the first scan line may form a dual gate of the second transistor together with the second gate electrode, and the second scan line may form a dual gate of the third transistor together with the third gate electrode.

In an embodiment, an area of the first gate electrode may be larger than an area of a channel region of the first transistor in a plan view.

In an embodiment, the first semiconductor layer may include polycrystalline silicon and the second semiconductor layer may include an oxide semiconductor.

According to one or more embodiments, there is provided a electronic device including display device, wherein display device includes a substrate, a first transistor disposed on the substrate and including a first semiconductor layer and a first gate electrode, a second transistor disposed on the first transistor and including a second semiconductor layer and a second gate electrode, and a light-emitting element disposed on the second transistor and electrically connected to the first transistor, wherein the first gate electrode of the first transistor and the second semiconductor layer of the second transistor are electrically connected through a contact hole.

### BRIEF DESCRIPTION OF THE DRAWINGS

The above and other aspects, features, and advantages of certain embodiments of the disclosure will be more apparent from the following description taken in conjunction with the accompanying drawings, in which:

The following drawings attached to this specification illustrate preferred embodiments of the disclosure and, together with the detailed description of the disclosure described below, serve to further understand the technical idea of the disclosure; therefore, the disclosure should not be interpreted as being limited to matters described in such drawings:

FIG. 1 is a schematic plan view of one example of a display device according to an embodiment;

FIG. 2 is a schematic block diagram of a structure of the display device of FIG. 1;

FIG. 3 is a schematic diagram of an equivalent circuit of one sub-pixel of the display device of FIG. 1;

FIG. 4 is a schematic layout diagram illustrating the positions of thin-film transistors, capacitors, etc., arranged in sub-pixels included in the display device of FIG. 1;

FIG. 5 is a schematic plan view illustrating an example of two adjacent sub-pixels of the display device of FIG. 1;

FIG. 6 is a schematic cross-sectional view illustrating a portion of the display device of FIG. 1;

FIG. 7 is an enlarged schematic cross-sectional view illustrating one example of a part A of FIG. 6; and

FIG. 8 is a schematic diagram of an example in which an electronic device including a display device according to embodiments is implemented as a head-mounted display.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction X, the axis of the second direction Y, and the axis of the third direction Z are not limited to three axes of a rectangular coordinate system, such as the X, Y, and Z – axes, and may be interpreted in a broader sense. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element’s relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described in detail with reference to the accompanying drawings. When describing embodiments with reference to the accompanying drawings, the same or corresponding elements are denoted by the same reference numerals, and redundant descriptions thereof are omitted.

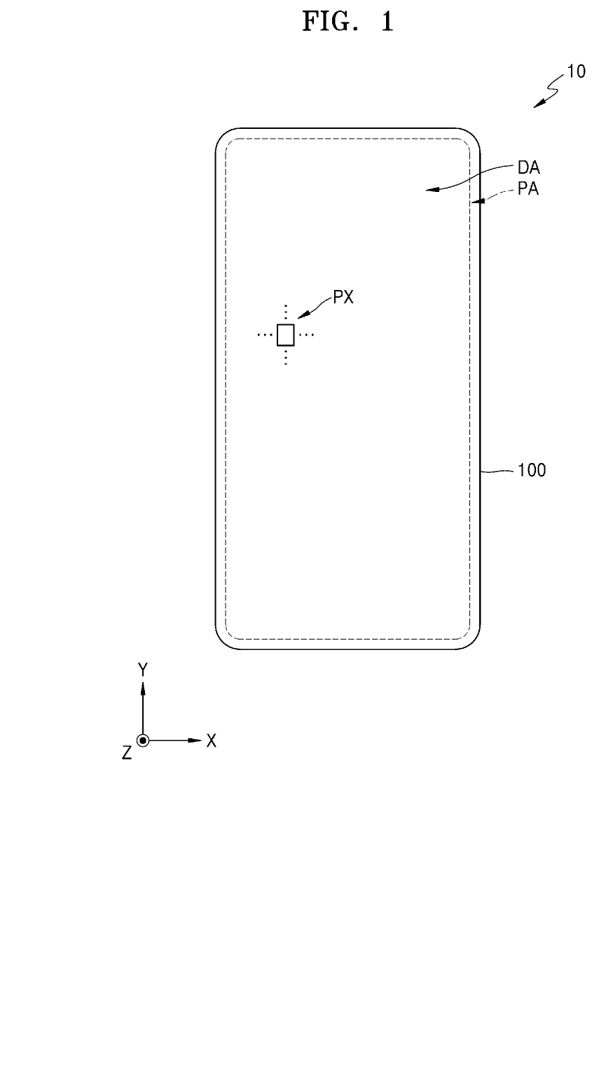

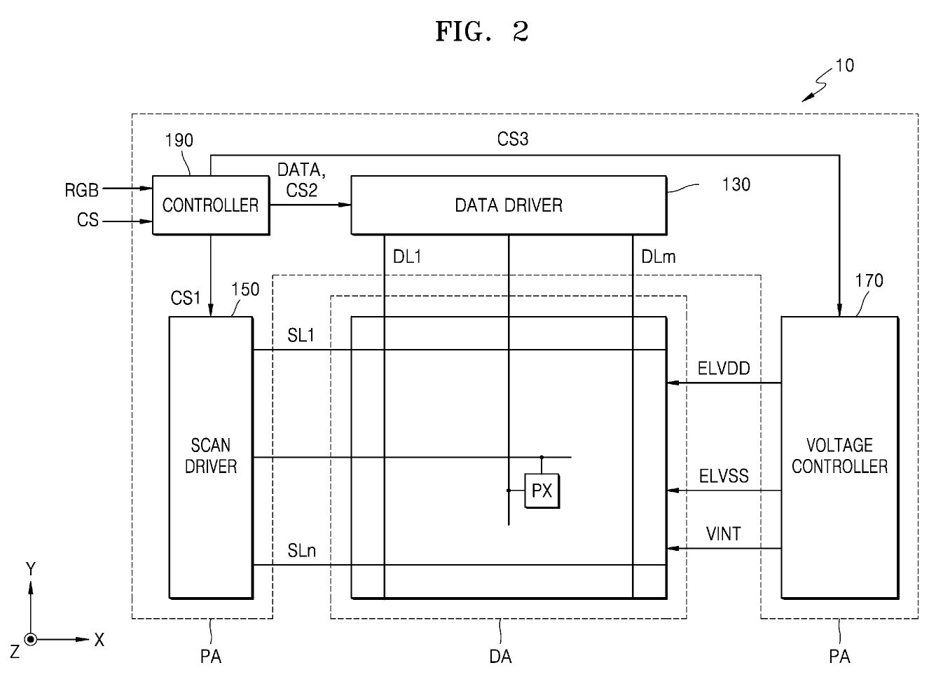

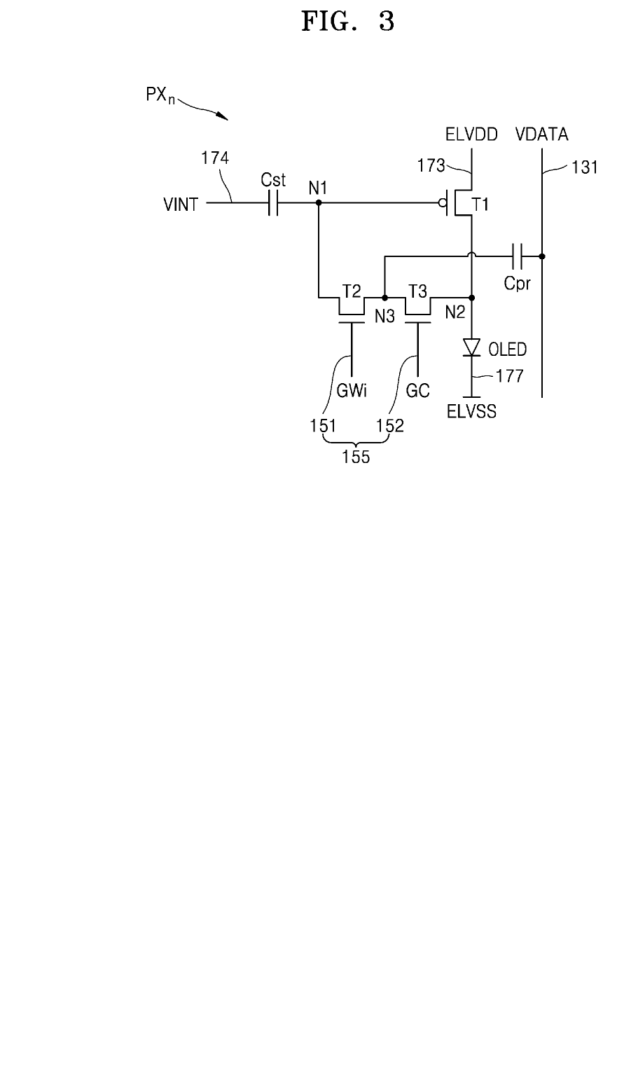

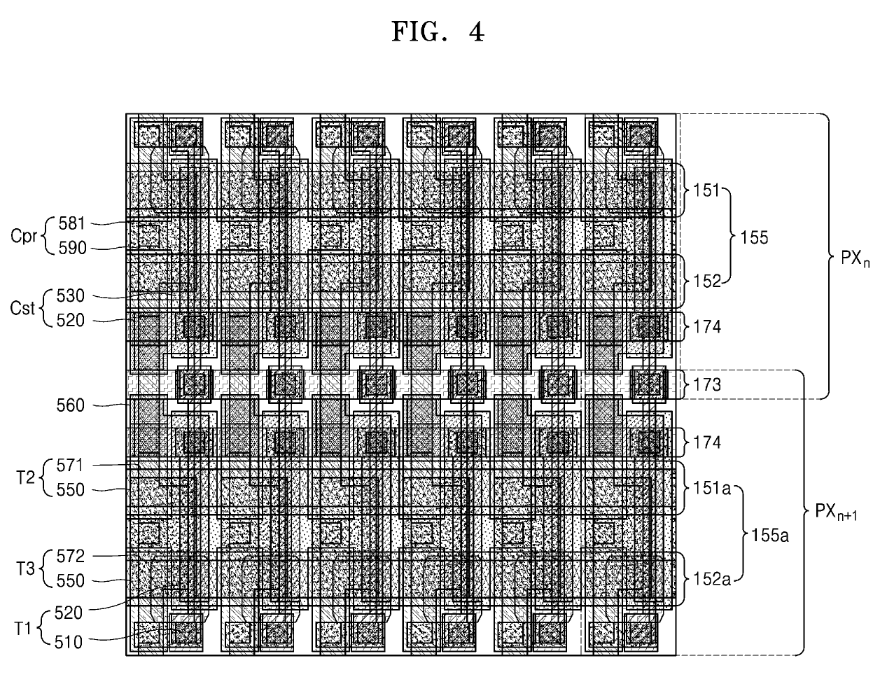

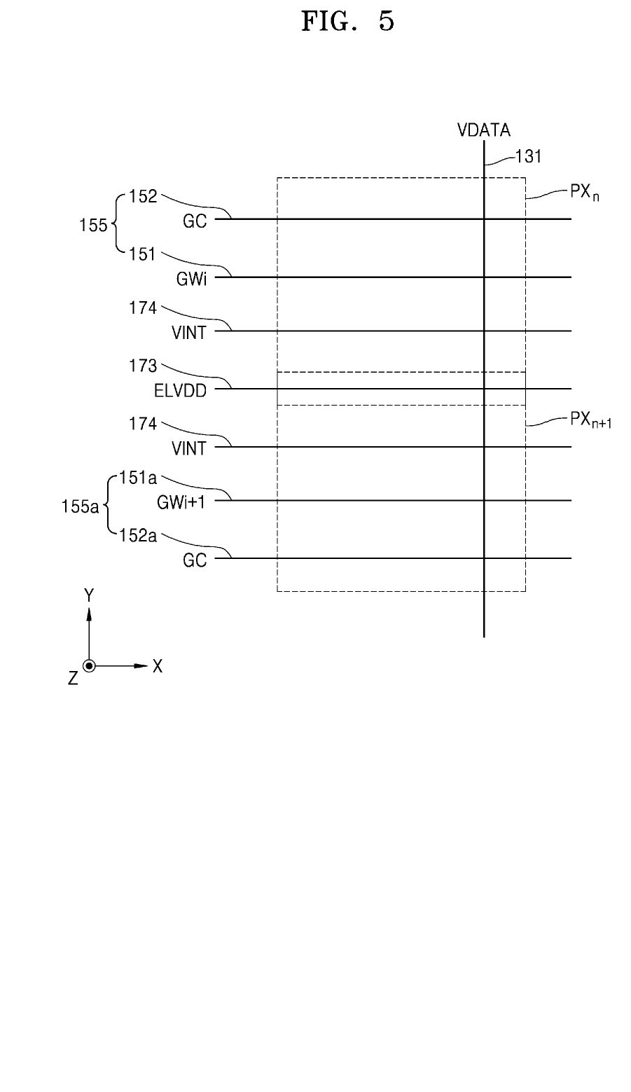

FIG. 1 is a schematic plan view of one example of a display device according to an embodiment, FIG. 2 is a schematic block diagram of a structure of the display device of FIG. 1, FIG. 3 is a schematic diagram of an equivalent circuit of one sub-pixel of the display device of FIG. 1, FIG. 4 is a schematic layout diagram illustrating the positions of thin-film transistors, capacitors, etc., arranged in sub-pixels included in the display device of FIG. 1, and FIG. 5 is a schematic plan view illustrating an example of two adjacent sub-pixels of the display device of FIG. 1.

First, referring to FIGS. 1 and 2, a display device 10 according to an embodiment may include a substrate 100 which has a display area DA for displaying an image and a peripheral area PA disposed outside the display area DA.

Scan lines SL1, ..., SLn extending along a first direction X, data lines DL1, ..., DLm extending along a second direction Y perpendicular to the first direction X, and sub-pixels PX may be disposed in the display area DA. A third direction Z may be perpendicular to the plane defined by the first direction X and the second direction Y. Here, m and n denote natural numbers.

Wirings, along which electrical signals are applied to the sub-pixels PX, may include scan lines SL1, ..., SLn, and data lines DL1, ..., DLm. The scan lines SL1, ..., SLn, for example, may be arranged in rows extending in the first direction X, to transmit scan signals to the sub-pixels PX. The data lines DL1, ..., DLm, for example, may be arranged in columns extending in the second direction Y, to transmit data signals to the sub-pixels PX. The sub-pixels PX may be positioned at intersections of the scan lines SL1, ..., SLn and the data lines DL1, ..., DLm.

The sub-pixels PX may each include a light-emitting element which emits red light, green light, blue light, or white light. For example, each sub-pixel PX may include an organic light-emitting diode OLED as a light-emitting element.

A data driver 130, a scan driver 150, a voltage controller 170, and a controller 190 may be arranged in the peripheral area PA. The data driver 130 may apply data signals to the display area DA, the scan driver 150 may apply scan signals to the display area DA, a voltage controller 170 may control voltages supplied to the display area DA, and the controller 190 may control the data driver 130, the scan driver 150, and the voltage controller 170 may be arranged.

The voltage controller 170 may generate and control a first voltage ELVDD, a second voltage ELVSS, and an initialization voltage VINT which are applied to the display area DA.

The first voltage ELVDD, the second voltage ELVSS, and the initialization voltage VINT may be applied to the sub-pixels PX. For example, the first voltage ELVDD may be a positive voltage, and the second voltage ELVSS may be a negative voltage or a ground voltage. For example, the second voltage ELVSS may have a lower level than the first voltage ELVDD.

The controller 190 may receive image signals RGB and control signals CS from the exterior (e.g., a system board). The controller 190 may generate image data by converting a data format of the image signals RGB to be appropriate to an interface between the data driver 130 and the controller 190. The controller 190 may apply the image data having the converted data format to the data driver 130.

The controller 190 may generate and output a first control signal CS1, a second control signal CS2, and a third control signal CS3, in response to the control signal CS applied from the exterior. The first control signal CS1 may be defined as a scan control signal and the second control signal CS2 may be defined as a data control signal. The first control signal CS1 may be applied to the scan driver 150. The second control signal CS2 may be applied to the data driver 130. The third control signal CS3 may be applied to the voltage controller 170.

The scan driver 150 may generate scan signals, in response to the first control signal CS1. The scan signals may be applied to the sub-pixels PX through the scan lines SL1, ..., SLn.

The data driver 130 may generate data voltages corresponding to the image data, in response to the second control signal CS2. The data voltages may be applied to the sub-pixels PX through the data lines DL1, ..., DLm. The data driver 130 may simultaneously apply the data voltages, which are generated in units of sub-pixel rows, to the sub-pixels PX through the data lines DL1, ..., DLm.

The sub-pixels PX may receive the data voltages, in response to the scan signals. The sub-pixels PX may display an image by emitting light of luminance corresponding to the data voltages. The sub-pixels PX may display an image by emitting light sequentially or simultaneously.

Referring to FIGS. 1 to 3, each of the sub-pixels PX may include a first transistor T1, a second transistor T2, a third transistor T3, and a light-emitting element OLED, which is electrically connected to the first transistor T1.

Among the sub-pixels PX, a sub-pixel PX, which is connected to an i-th scan line 155 among the scan lines SL1, ..., SLn and a j-th data line 131 among the data lines DL1, ..., DLm, may be defined as a first sub-pixel PXn. Here, i is a natural number greater than 0 and less than or equal to n, and j is a natural number greater than 0 and less than or equal to m.

The i-th scan line 155 may include a first scan line 151 and a second scan line 152. The first scan line 151 and the second scan line 152 may transmit scan signals GWi and GC, respectively, to the first sub-pixel PXₙ.

The j-th data line 131 may transmit a data voltage VDATA to the first sub-pixel PXₙ. The data voltage VDATA may have a voltage level corresponding to the image signal RGB which is input to the display device 10.

A first voltage line 173 may transmit the first voltage ELVDD to the first sub-pixel PXₙ, a second voltage line 177 may transmit the second voltage ELVSS to the first sub-pixel PXₙ, and an initialization voltage line 174 may transmit the initialization voltage VINT to the first sub-pixel PXₙ.

For example, a first transistor T1 may be a P-type transistor which has a low-temperature polycrystalline silicon (LTPS) semiconductor layer. However, this is an example, and the first transistor T1 may be an N-type transistor.

The second and third transistors T2 and T3 may each be a N-type transistor having an oxide semiconductor layer. However, this is an example, and the second and/or third transistors T2 and/or T3 may be P-type transistors.

The first transistor T1 may include a first gate electrode, a first driving electrode, and a second driving electrode. The first gate electrode of the first transistor T1 may be connected to a first node N1, the first driving electrode may be connected to the first voltage line 173, and the second driving electrode may be connected to a second node N2. The first transistor T1 may be referred to as a driving transistor.

The second transistor T2 may include a second gate electrode, a first switching electrode, and a second switching electrode. The second gate electrode of the second transistor T2 may be connected to the first scan line 151, the first switching electrode may be connected to the first node N1, and the second switching electrode may be connected to a third node N3. The second transistor T2 may be referred to as a switching transistor or a scan transistor.

The third transistor T3 may include a third gate electrode, a first initialization electrode, and a second initialization electrode. The third gate electrode of the third transistor T3 may be connected to the second scan line 152, the first initialization electrode may be connected to the third node N3, and the second initialization electrode may be connected to the second node N2. The third transistor T3 may be referred to as an initialization transistor.

For example, each of the sub-pixels PX may further include a first capacitor Cst and a second capacitor Cpr.

A first electrode of the first capacitor Cst may be connected to the first node N1, and a second electrode of the first capacitor Cst may be connected to the initialization voltage line 174. The first capacitor Cst may be referred to as a storage capacitor.

The first capacitor Cst may store a voltage between the first node N1 and the initialization voltage line 174. An amount of driving current which flows through the first transistor T1 may be determined based on the voltage stored in the first capacitor Cst. The light-emitting element OLED may emit light based on the driving current.

A first electrode of the second capacitor Cpr may be connected to the third node N3, and a second electrode of the second capacitor Cpr may be connected to the j-th data line 131.

The second capacitor Cpr may store a voltage between the third node N3 and the j-th data line 131. The second capacitor Cpr may also initialize the first voltage ELVDD through the second node N2 and the third transistor T3.

The light-emitting element OLED may include a first electrode connected to the second node N2 and a second electrode connected to the second voltage line 177. The first electrode of the light-emitting element OLED may be referred to as an anode electrode or a pixel electrode, and the second electrode of the light-emitting element OLED may be referred to as a cathode electrode or a common electrode.

Referring to FIGS. 4 and 5, further referring to FIG. 2, two sub pixels, i.e., a first sub-pixel PXₙ and a second sub-pixel PXₙ₊₁, which are arranged adjacent to each other in a second direction Y perpendicular to a first direction X with respect to the first voltage line 173, may share the first voltage ELVDD with each other. In some embodiments, the first sub-pixel PXₙ and the second sub-pixel PXₙ₊₁ may be symmetrical with respect to the first voltage line 173.

Each of the first sub-pixel PXₙ and the second sub-pixel PXₙ₊₁ may include a first scan line 151 and 151a, a second scan line 152 and 152a, and an initialization voltage line 174 that are parallel to the first direction X.

In some embodiments, the second gate electrode or a second sub-gate electrode of the second transistor T2 of the first sub-pixel PXₙ may be connected to the first scan line 151 of the i-th scan line 155, the third gate electrode or a third sub-gate electrode of the third transistor T3 of the first sub-pixel PXₙ may be connected to the second scan line 152 of the i-th scan line 155, and the first driving electrode of the first transistor T1 of the first sub-pixel PXₙ may be connected to the first voltage line 173 which is shared with the second sub-pixel PXₙ₊₁.

The second electrode of the first capacitor Cst of the first sub-pixel PXₙ may be connected to the initialization voltage line 174 to which the initialization voltage VINT is applied, and the second electrode of the second capacitor Cpr of the first sub-pixel PXₙ may be connected to the j-th data line 131 to which the data voltage VDATA is applied.

The second gate electrode or a second sub-gate electrode of the second transistor T2 of the second sub-pixel PXₙ₊₁ may be connected to a first scan line 151a of an i+1-th scan line 155a, the third gate electrode or a third sub-gate electrode of the third transistor T3 of the second sub-pixel PXₙ₊₁ may be connected to a second scan line 152a of the i+1-th scan line 155a, and the first driving electrode of the first transistor T1 of the second sub-pixel PXₙ₊₁ may be connected to the first voltage line 173 which is shared with the first sub-pixel PXₙ.

The second electrode of the first capacitor Cst of the second sub-pixel PXₙ₊₁ may be connected to the initialization voltage line 174 to which the initialization voltage VINT is applied, and the second electrode of the second capacitor Cpr of the second sub-pixel PXₙ₊₁ may be connected to the j-th data line 131 to which the data voltage VDATA is applied.

For example, an i-th scan signal GWi which is transmitted to the first sub-pixel PXₙ through the first scan line 151 and an i+1-th scan signal GWi+1 which is transmitted to the second sub-pixel PXₙ₊₁ through the first scan line 151a may be sequentially generated in the scan driver 150.

Further, an i-th scan signal GC which is transmitted to the first sub-pixel PXₙ through the second scan line 152 and an i+1-th scan signal GC which is transmitted to the second sub-pixel PXₙ₊₁ through the second scan line 152a may be global gate signals for synchronizing the sub-pixels PX.

For example, a longitudinal direction of each of the first scan line 151 of the i-th scan line 155, the second scan line 152 of the i-th scan line 155, the first voltage line 173, and the initialization voltage line 174, which are connected to the first sub-pixel PXₙ, may be parallel to the first direction X.

A longitudinal direction of each of the first scan line 151a of the i+1-th scan line 155a, the second scan line 152a of the i+1-th scan line 155a, the first voltage line 173, and the initialization voltage line 174, which are connected to the second sub-pixel PXₙ₊₁, may also be parallel to the first direction X.

For example, since the first sub-pixel PXₙ and the second sub-pixel PXₙ₊₁ share the first voltage line 173, the longitudinal direction of each of the first scan line 151 of the i-th scan line 155, the second scan line 152 of the i-th scan line 155, the first voltage line 173, the initialization voltage line 174, the first scan line 151a of the i+1-th scan line 155a, and the second scan line 152a of the i+1-th scan line 155a may be parallel to the first direction X.

Further, the j-th data line 131, through which the data voltage VDATA is applied to the first sub-pixel PXₙ and the second sub-pixel PXₙ₊₁, may be arranged in the second direction Y perpendicular to the first direction X.

Accordingly, the display device 10 according to an embodiment may have improved integration density because the first sub-pixel PXₙ and the second sub-pixel PXₙ₊₁ share the first voltage line 173 without having first voltage lines individually.

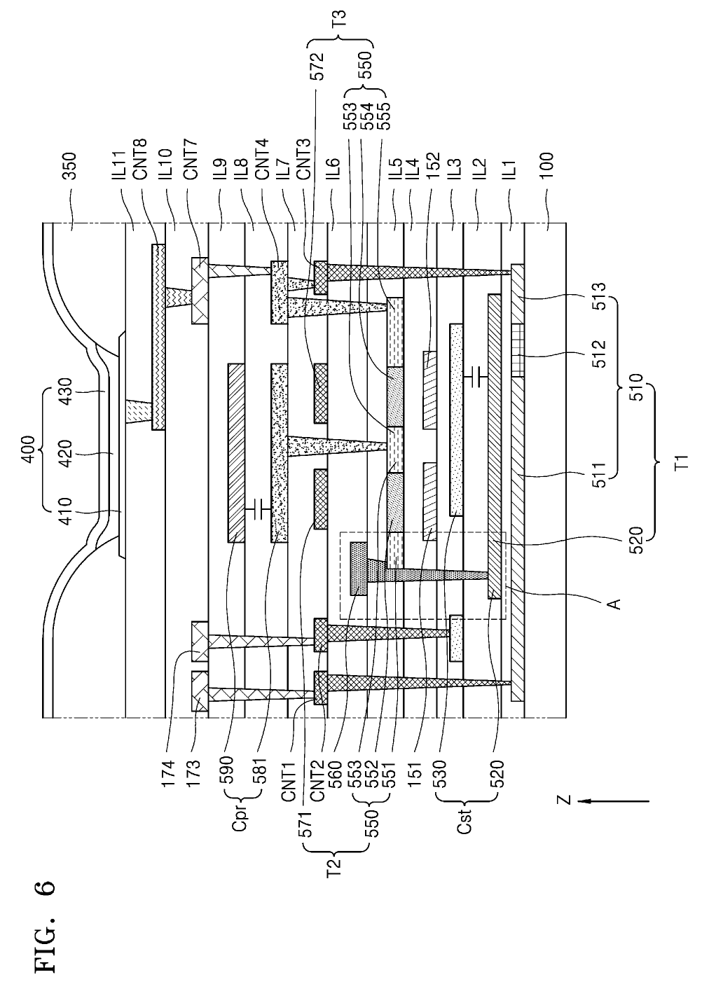

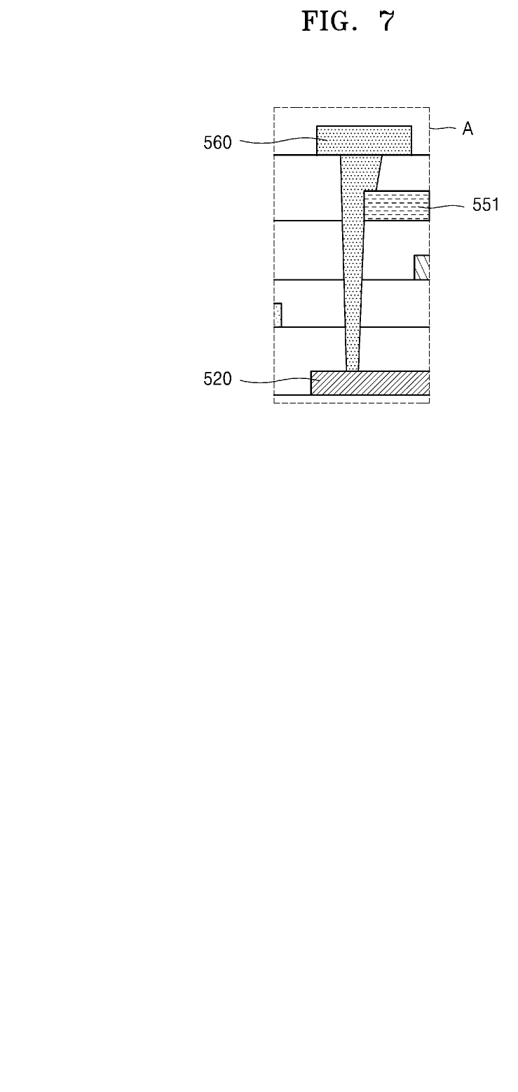

FIG. 6 is a schematic cross-sectional view illustrating a portion of the display device of FIG. 1, and FIG. 7 is an enlarged schematic cross-sectional view illustrating one example of a part A shown in FIG. 6. For example, FIG. 6 may illustrate an example of the pixel PX illustrated in FIGS. 1 to 5.

Referring to FIGS. 6 and 7 together with FIGS. 2 to 5, a sub-pixel PX according to an embodiment may include, on a substrate 100 thereof, a first transistor T1, a second transistor T2 and a third transistor T3 positioned on the first transistor T1, a light-emitting element 400 positioned on the second transistor T2 and the third transistor T3 and electrically connected to the first transistor T1, a first capacitor Cst, and a second capacitor Cpr. The second transistor T2 and the third transistor T3 may be located on the same layer.

In some embodiments, the substrate 100 may be made of a transparent glass material mainly containing SiO₂. However, it is not limited thereto, and the substrate 100 may also be made of a transparent plastic material. The plastic material may be one selected from the group consisting of: polyethersulphone (PES), polyacrylate (PAR), polyetherimide (PEI), polyethylene naphthalate (PEN), polyethyleneterepthalate (PET), polyphenylene sulfide (PPS), polyarylate, polyimide, polycarbonate (PC), cellulose triacetate (TAC), and cellulose acetate propionate (CAP).

A first semiconductor layer 510 may be formed on the substrate 100. The first semiconductor layer 510 may include a first source region 511, a first drain region 513, and a first channel region 512 located between the first source region 511 and the first drain region 513.

In some embodiments, the first semiconductor layer 510 may include a first source region 511 and a first drain region 513, which are doped with impurity, on respective opposite sides of the first channel region 512. For example, the impurity may vary according to the type of the first transistor T1 and may include an N-type impurity or a P-type impurity. For example, the first channel region 512, the first source region 511 located on a side of the first channel region 512, and the first drain region 513 located on another side of the first channel region 512 may be referred to as the first semiconductor layer 510.

The first source region 511 or the first drain region 513 which is formed by doping may also be interpreted as a source electrode (or a first driving electrode) or a drain electrode (or a second driving electrode) of the first transistor T1 in some cases. In some embodiments, the positions of the first source region 511 and the first drain region 513 may be switched with each other according to the impurity doped to the first semiconductor layer 510.

The first semiconductor layer 510 may include polycrystalline silicon. For example, the first semiconductor layer 510 may be a layer that includes low-temperature polycrystalline silicon (LTPS), but is not limited thereto, and may also be a layer that includes an oxide semiconductor.

As an optional embodiment, a buffer layer may also be formed between the substrate 100 and the first semiconductor layer 510. The buffer layer may improve the characteristics of the polycrystalline silicon by shielding impurities during a crystallization process for forming the polycrystalline silicon, and a flat surface may be provided on the buffer layer.

A first insulating layer IL1 may be formed on the first semiconductor layer 510 to cover the first semiconductor layer 510. A first conductive layer including a first gate electrode 520 may be formed on the first insulating layer IL1. In a plan view, the first gate electrode 520 may have an area which is wider than an area of the first channel region 512 of the first transistor T1.

The first gate electrode 520 may form the first transistor T1 together with the first semiconductor layer 510. The first transistor T1 may receive a first voltage ELVDD from the first source region 511 and supply a driving current to a light-emitting element 400.

The first gate electrode 520 may also function as a first gate electrode 520 of the first capacitor Cst. Accordingly, the integration density of the display device 10 may be increased, and thus the areas of the first capacitor Cst and the first transistor T1 may be increased, thereby providing a high-quality image. However, embodiments are not limited thereto. As another embodiment, the first gate electrode 520 of the first capacitor Cst may be an independent component, separate from the first gate electrode 520 of the first transistor T1.

A second insulating layer IL2 may be formed on the first conductive layer to cover the second insulating layer IL2. A second conductive layer which includes a second electrode 530 of the first capacitor Cst may be formed on the second insulating layer IL2. The second electrode 530 of the first capacitor Cst may form the first capacitor Cst together with the first gate electrode 520 of the first capacitor Cst.

A third insulating layer IL3 may be formed on the second conductive layer to cover the third insulating layer IL3. A third conductive layer including a first scan line 151 and a second scan line 152, to which scan signals GWi and GC are applied, respectively, may be formed on the third insulating layer IL3.

A fourth insulating layer IL4 may be formed on the third conductive layer to cover the fourth insulating layer IL4. A second semiconductor layer 550 may be formed on the fourth insulating layer IL4. The second semiconductor layer 550 may include a second source region 551, a second channel region 552, a second drain region 553, a third source region 553, a third channel region 554, and a third drain region 555.

The second channel region 552 may be located between the second source region 551 and the second drain region 553, and the third channel region 554 may be located between the third source region 553 and the third drain region 555. In some embodiments, the second drain region 553 and the third source region 553 may refer to the same region.

The positions of the second source region 551 and the second drain region 553 may be switched with each other according to impurity doped to the second semiconductor layer 550, and the positions of the third source region 553 and the third drain region 555 may be switched with each other according to impurity doped to the second semiconductor layer 550.

The second semiconductor layer 550 may be a layer that includes an oxide semiconductor, but is not limited thereto, and may alternatively be a layer that includes polycrystalline silicon, for example, low-temperature polycrystalline silicon (LTPS).

A fifth insulating layer IL5 may be formed on the second semiconductor layer 550 to cover the fifth insulating layer IL5. A fourth conductive layer 560, which electrically connects the first gate electrode 520 and the second source region 551 of the second semiconductor layer 550 through a contact hole, may be formed on the fifth insulating layer IL5. At least a portion of the fourth conductive layer 560 may overlap the first gate electrode 520 and the second semiconductor layer 550 in a vertical direction Z.

In some embodiments, the contact hole connected to the fourth conductive layer 560 may expose a side surface of the second source region 551 of the second semiconductor layer 550, and may also expose at least a portion of an upper surface of the first gate electrode 520. Accordingly, the fourth conductive layer 560, the second source region 551, and the first gate electrode 520 may be electrically connected. For example, the fourth conductive layer 560 may be a first node N1 illustrated in FIG. 3.

For example, the first transistor T1 and the second transistor T2 may be arranged on different layers, and the first gate electrode 520 of the first transistor T1 and the second source region 551 of the second transistor T2 may be connected through a single contact hole, thereby providing the display device 10 with improved integration density.

A sixth insulating layer IL6 may be formed on the fourth conductive layer 560 to cover the sixth insulating layer IL6. A fifth conductive layer, which includes contacts CNT1, CNT2, and CNT3, a second gate electrode 571, and a third gate electrode 572, may be formed on the sixth insulating layer IL6.

The second gate electrode 571 and the third gate electrode 572 may overlap the second channel region 552 and the third channel region 554, respectively. The second gate electrode 571 may form the second transistor T2 together with the second source region 551, the second channel region 552, and the second drain region 553. In some embodiments, the third gate electrode 572 may form the third transistor T3, which is located on the same layer as the second transistor T2, together with the third source region 553, the third channel region 554, and the third drain region 555.

For example, the first scan line 151 and the second scan line 152, which are located on the third insulating layer IL3 and located on the same layer between the first transistor T1 and the second transistor T2, may be referred to as a second sub-gate electrode 151 and a third sub-gate electrode 152, respectively. As a result, the second sub-gate electrode 151 and the third sub-gate electrode 152 may form a dual gate of the second transistor T2 and a dual gate of the third transistor T3 together with the second gate electrode 571 and the third gate electrode 572, respectively.

The second sub-gate electrode 151 may be formed to overlap the second gate electrode 571. In a plan view, an area of the second sub-gate electrode 151 may be larger than an area of the second gate electrode 571. The third sub-gate electrode 152 may also be formed to overlap the third gate electrode 572. In a plan view, an area of the third sub-gate electrode 152 may be larger than an area of the third gate electrode 572.

In case that the second transistor T2 and the third transistor T3 have the dual gates, currents flowing along the second transistor T2 and the third transistor T3 may be controlled more precisely, switching speed of the second transistor T2 and the third transistor T3 may be improved by the interaction between the dual gates, and the second transistor T2 and the third transistor T3 may be driven with low power.

A seventh insulating layer IL7 may be formed on the fifth conductive layer to cover the seventh insulating layer IL7. A sixth conductive layer, which includes a fourth contact CNT4 and a first electrode 581 of the second capacitor Cpr, may be formed on the seventh insulating layer IL7.

The first electrode 581 of the second capacitor Cpr may be electrically connected between the second channel region 552 and the third channel region 554 of the second semiconductor layer 550 through a contact hole (e.g., single contact hole). The contact hole may expose at least a portion of an area between the second channel region 552 and the third channel region 554.

For example, the first electrode 581 of the second capacitor Cpr may be electrically connected to the second transistor T2 and the third transistor T3 through the single contact hole, other than two different contact holes, thereby improving the integration density of the display device 10.

An eighth insulating layer IL8 may be formed on the sixth conductive layer to cover the eighth insulating layer IL8. A seventh conductive layer, which includes a second electrode 590 of the second capacitor Cpr, may be formed on the eighth insulating layer IL8.

The second electrode 590 of the second capacitor Cpr may be arranged to overlap the first electrode 581 of the second capacitor Cpr. The second electrode 590 of the second capacitor Cpr may also form the second capacitor Cpr together with the first electrode 581 of the second capacitor Cpr.

In some embodiments, the second electrode 590 of the second capacitor Cpr may include a data line 131 to which a data voltage VDATA is applied.

A ninth insulating layer IL9 may be formed on the seventh conductive layer to cover the ninth insulating layer IL9. An eighth conductive layer may be formed on the ninth insulating layer IL9. The eighth conductive layer may include a first voltage line 173 to which a first voltage ELVDD is applied, an initialization voltage line 174 to which an initialization voltage VINT is applied, and a seventh contact CNT7.

The first voltage line 173 may be connected to the first source region 511 of the first transistor T1 through the first contact CNT1 formed on the sixth insulating layer IL6. This may allow the first voltage ELVDD to be applied to the first source region 511 of the first transistor T1.

The initialization voltage line 174 may be connected to the second electrode 530 of the first capacitor Cst through the second contact CNT2 formed on the sixth insulating layer IL6. This may allow the initialization voltage VINT to be stored in the first capacitor Cst.

The first insulating layer IL1, the second insulating layer IL2, the third insulating layer IL3, the fourth insulating layer IL4, the fifth insulating layer IL5, the sixth insulating layer IL6, the seventh insulating layer IL7, the eighth insulating layer IL8, and the ninth insulating layer IL9 may each be formed of silicon nitride and/or silicon oxide.

A tenth insulating layer IL10 may be formed on the eighth conductive layer to cover the same. A ninth conductive layer including an eighth contact CNT8 may be formed on the tenth insulating layer IL10.

The eighth contact CNT8 may be electrically connected to the third drain region 555 of the third transistor T3 and the first drain region 513 of the first transistor T1 through the seventh contact CNT7 located on the ninth insulating layer IL9 and the fourth contact CNT4 located on the seventh insulating layer IL7. The eighth contact CNT8 may also be electrically connected to a pixel electrode 410 of the light-emitting element 400. For example, the pixel electrode 410 of the light-emitting element 400 may be electrically connected to the first drain region 513 of the first transistor T1 and the third drain region 555 of the third transistor T3 through the eighth contact CNT8.

An eleventh insulating layer IL11 may be formed on the ninth conductive layer to cover the same. The light-emitting element 400 may be positioned on the eleventh insulating layer IL11, and may include a pixel electrode 410, a common electrode 430, and an intermediate layer 420 interposed between the pixel electrode 410 and the common electrode 430 and including an emission layer. The light-emitting element 400 may be, for example, an organic light-emitting diode (OLED).

In an embodiment, the pixel electrode 410 may be an anode of an organic light-emitting diode (OLED), and the common electrode 430 may be a cathode of the organic light-emitting diode (OLED). However, embodiments are not limited thereto, and the pixel electrode 410 may be a cathode of the organic light-emitting diode (OLED) and the common electrode 430 may be an anode of the organic light-emitting diode (OLED), according to a driving method of a display device. In case that holes and electrons are injected into the intermediate layer 420 from the pixel electrode 410 and the common electrode 430, respectively, excitons are produced by the combination of the injected holes and electrons. The excitons may change from an excited state to a ground state, thereby emitting light.

The tenth insulating layer IL10 and the eleventh insulating layer IL11 may each be formed of an organic material or a film stack including an organic material and an inorganic material. Examples of the organic material may include an imide-based polymer, a general-purpose polymer such as polymethylmethacrylate (PMMA) or polystyrene (PS), a polymer derivative having a phenolic group, an acryl-based polymer, an aryl ether-based polymer, an amide-based polymer, a fluorine-based polymer, a p-xylene-based polymer, a vinyl alcohol-based polymer, and a blend thereof.

The first to ninth conductive layers may include at least one of aluminum (Alr, platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu).

For example, the pixel electrode 410 may be a translucent electrode or a reflective electrode. In case that the pixel electrode 410 is a translucent electrode, it may include, for example, ITO, IZO, ZnO, In2O3, IGO, or AZO. In case that the pixel electrode 410 is a reflective electrode, the pixel electrode 410 may have a reflective film, which includes Ag, Mg, Al, Pt, Pd, Au, Ni, Nd, Ir, Cr, and compounds thereof, and a layer formed of ITO, IZO, ZnO, In2O3, IGO, or AZO. Of course, embodiments are not limited thereto, and the pixel electrode 410 may include various materials, and may also be modified in various ways, such as having a single-layer or multi-layer structure.

A pixel defining layer 350 covering an edge of the pixel electrode 410 may be arranged on the eleventh insulating layer IL11. The pixel defining layer 350 may play a role or defining the sub-pixel PX by having an opening corresponding to each sub-pixel PX, e.g., an opening exposing at least a central portion of the pixel electrode 410. The pixel defining layer 350 may also increase a distance between the edge of the pixel electrode 410 and the common electrode 430, thereby suppressing an occurrence of an arc therebetween. The pixel defining layer 350 may be formed of an organic material such as polyimide or hexamethyldisiloxane (HMDSO).

An intermediate layer 420 may be formed on the pixel electrode 410 which is exposed through the opening of the pixel defining layer 350. The intermediate layer 420 may include a low-molecular weight material or a high-molecular weight material. In case that the intermediate layer 420 includes a low-molecular weight material, the intermediate layer 420 may have a single-layer structure or multi-layer structure including a hole injection layer (HIL), a hole transport layer (HTL), an emission layer (EML), an electron transport layer (ETL), or an electron injection layer (EIL), and may include various organic materials including copper phthalocyanine (CuPc), N,N′-di(naphthalene-1-yl)-N,N′-diphenyl-benzidine (NPB), tris-8-hydroxyquinoline aluminum (Alq3), and the like. These layers may be formed by vacuum deposition.

In case that the intermediate layer 420 includes a high-molecular weight material, the intermediate layer 420 may usually have a structure including a hole transport layer (HTL) and an emission layer (EML). In this instance, the hole transport layer may include poly(3,4-ethylenedioxythiophene) (PEDOT), and the emission layer may include a high molecular weight material such as poly-phenylenevinylene (PPV)-based high-molecular weight material, and polyfluorene-based high-molecular weight material. The structure of the intermediate layer 420 is not limited to that described above and may have various structures. For example, the intermediate layer 420 may include a layer that is integrally formed throughout pixel electrodes 410, or a layer that is patterned to correspond to each of the pixel electrodes 410.

The common electrode 430 may be arranged to cover the display area (DA in FIG. 1). For example, the common electrode 430 may be formed as an integral body (or single body) to cover the light-emitting elements 400. The common electrode 430 may be a translucent electrode or a reflective electrode. In case that the common electrode 430 is a translucent electrode, the common electrode 430 may include a layer formed of a metal having a low work function, i.e., Li, Ca, LiF/Ca, LiF/Al, Al, Ag, Mg, and any compound thereof (such as, LiF), or materials with multilayer structures such as LiF/Ca or LiF/Al, and a translucent conductive layer such as ITO, IZO, ZnO, In2O3, or the like. In case that the common electrode 430 is a reflective electrode, the common electrode 430 may include a layer formed of a metal such as, Li, Ca, Al, Ag, Mg, and any compound thereof (such as, LiF), or materials with multilayer structures such as LiF/Ca or LiF/Al. However, the configuration and materials of the common electrode 430 are not limited thereto and the common electrode 430 may be variously modified.

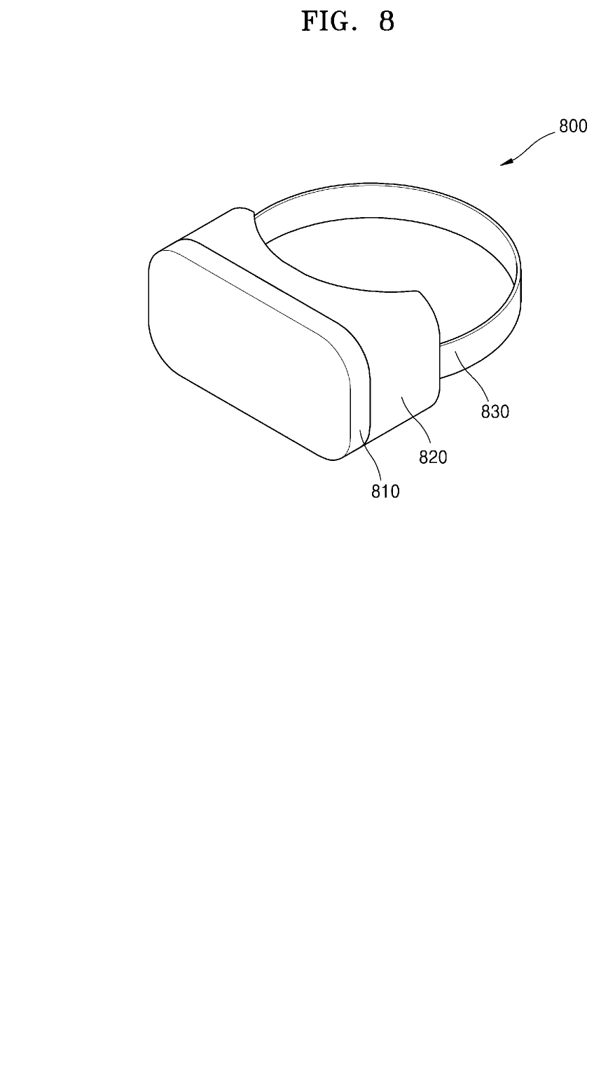

FIG. 8 is a schematic diagram of an example in which an electronic device including a display device according to embodiments is implemented as a head-mounted display.

Referring to FIG. 8, an electronic device including a display device may be implemented as a head-mounted display (HMD) 800. The HMD 800 may include a display unit 810, a main body unit 820, and a wearing unit 830.

For example, the display unit 810 may include the display device 10 according to the embodiments of FIGS. 1 to 7 to implement a screen. The main body unit 820 may include a controller that applies a scan signal and a data signal to the display unit 810, a touch sensor, or an acoustic sensor. A user may wear the HMD 800 using the wearing unit 830.

However, this is an example and the electronic device is not limited to the HMD 800. For example, the electronic device may be any electronic device including a display device such as a virtual reality (VR) device, a mobile phone, a smart phone, a tablet computer, a digital television (TV), a three-dimensional (3D) TV, a personal computer (PC), a home appliance, a laptop computer, a personal digital assistant (PDA), a portable multimedia player (PMP), a digital camera, a music player, a portable game console, a navigator, etc.

According to one or more embodiments, two sub-pixels which are vertically adjacent to each other may share a first voltage line, and a first transistor and a second transistor may be positioned on different layers such that a gate electrode of the first transistor and a source or drain region of the second transistor may be electrically connected through a single contact hole, thereby providing a display device having improved integration density.

However, the effects obtainable through the disclosure are not limited to the effects described above, and other technical effects not mentioned will be clearly understood by those skilled in the art from the description of the disclosure described below.

While the disclosure has been herein described with regard to a limited number of embodiments and drawings, embodiments are not limited thereto and it is obvious to those skilled in the art that various modifications and changes may be made thereto within the technical aspects of the present disclosure and the equivalent scope of the appended claims.

What is claimed is:

1. A display device comprising:
a substrate;
a first transistor disposed on the substrate and comprising a first semiconductor layer and a first gate electrode;
a second transistor disposed on the first transistor and comprising a second semiconductor layer and a second gate electrode; and
a light-emitting element disposed on the second transistor and electrically connected to the first transistor,
wherein the first gate electrode of the first transistor and the second semiconductor layer of the second transistor are electrically connected to each other through a contact hole.

2. The display device of claim 1, further comprising:
a conductive layer disposed on an insulating layer which covers the second semiconductor layer, and electrically connected to the first gate electrode and the second semiconductor layer through the contact hole,
wherein at least a portion of the conductive layer vertically overlaps the first gate electrode and the second semiconductor layer.

3. The display device of claim 1, wherein
the contact hole exposes a side surface of a source region of the second transistor.

4. The display device of claim 1, further comprising:
a third transistor,
wherein the third transistor and the second transistor are disposed on a same layer, and
the third transistor comprises the second semiconductor layer and a third gate electrode.

5. The display device of claim 4, further comprising
a first scan line and a second scan line disposed on a same layer between the first transistor and the second transistor,
wherein the first scan line forms a dual gate of the second transistor together with the second gate electrode, and
the second scan line forms a dual gate of the third transistor together with the third gate electrode.

6. The display device of claim 5, wherein
the first scan line and the second scan line are arranged parallel to each other.

7. The display device of claim 5, further comprising:
a first voltage line and an initialization voltage line disposed on a same layer between the second gate electrode and the light-emitting element.

8. The display device of claim 7, wherein
the first voltage line and the initialization voltage line are arranged parallel to the first scan line.

9. The display device of claim 7, wherein
two sub-pixels share a first voltage, and
the two sub-pixels are arranged adjacent to each other in a direction perpendicular to a longitudinal direction of the first voltage line with respect to the first voltage line.

10. The display device of claim 1, wherein
the first semiconductor layer comprises polycrystalline silicon, and
the second semiconductor layer comprises an oxide semiconductor.

11. A display device comprising:
a substrate comprising a display area and a peripheral area disposed outside the display area;
a plurality of sub-pixels disposed in the display area; and
a plurality of first voltage lines extending in a first direction and that apply a first voltage to the plurality of sub-pixels,
wherein two sub-pixels share a first voltage line of the plurality of first voltage lines, and
the two sub-pixels are arranged adjacent to each other in a second direction perpendicular to the first direction with respect to the first voltage line.

12. The display device of claim 11, wherein
the two sub-pixels are symmetrical with respect to the first voltage line.

13. The display device of claim 11, wherein
each of the plurality of sub-pixels comprises:
a first transistor disposed on the substrate and comprising a first semiconductor layer and a first gate electrode;
a second transistor disposed on the first transistor and comprising a second semiconductor layer and a second gate electrode; and
a light-emitting element disposed on the second transistor and electrically connected to the first transistor, and
the first gate electrode of the first transistor and the second semiconductor layer of the second transistor are electrically connected through a contact hole.

14. The display device of claim 13, further comprising:
a conductive layer disposed on an insulating layer which covers the second semiconductor layer, and electrically connected to the first gate electrode and the second semiconductor layer through the contact hole,
wherein at least a portion of the conductive layer vertically overlaps the first gate electrode and the second semiconductor layer.

15. The display device of claim 13, wherein
the contact hole exposes a side surface of a source region of the second transistor.

16. The display device of claim 13, further comprising:
a third transistor,
wherein the third transistor and the second transistor are disposed on a same layer, and
the third transistor comprises the second semiconductor layer and a third gate electrode.

17. The display device of claim 16, further comprising
a first scan line and a second scan line disposed on a same layer between the first transistor and the second transistor,
wherein the first scan line forms a dual gate of the second transistor together with the second gate electrode, and
the second scan line forms a dual gate of the third transistor together with the third gate electrode.

18. The display device of claim 13, wherein
an area of the first gate electrode is larger than an area of a channel region of the first transistor in a plan view.

19. The display device of claim 13, wherein
the first semiconductor layer comprises polycrystalline silicon, and
the second semiconductor layer comprises an oxide semiconductor.

20. An electronic device comprising:
a display device comprising:
a substrate;
a first transistor disposed on the substrate and comprising a first semiconductor layer and a first gate electrode;
a second transistor disposed on the first transistor and comprising a second semiconductor layer and a second gate electrode; and
a light-emitting element disposed on the second transistor and electrically connected to the first transistor,
wherein the first gate electrode of the first transistor and the second semiconductor layer of the second transistor are electrically connected to each other through a contact hole.
